(19) United States
(12) Patent Application Publication
(10) Pub. No.: US 2025/0185152 A1
(43) Pub. Date: Jun. 5, 2025

(54) CIRCUIT BOARD AND DISPLAY DEVICE HAVING SAME

(71) Applicants: K-Tronics (Suzhou) Technology Co., Ltd., Suzhou, Jiangsu (CN); BOE Technology Group Co., Ltd., Beijing (CN)

(72) Inventor: Honglei XU, Beijing (CN)

(21) Appl. No.: 18/844,984

(22) PCT Filed: May 12, 2023
(86) PCT No.: PCT/CN2023/093986

§ 371 Date: Sep. 9, 2024

(30) Foreign Application Priority Data
Jun. 14, 2022 (CN) 202210672765.4

(51) Int. Cl. H05K 1/02; H05K 7/20

(52) U.S. Cl. CPC H05K 1/0206; H05K 7/20954

(57) ABSTRACT

A circuit board and a display device having same. The circuit board comprises: a circuit board body (1), wherein a part mounting face (11) is formed on one side of the circuit board body (1); a base face (12) is formed on the other side of the circuit board body (1); the part mounting face (11) is provided with a heat dissipation bonding pad (2); the circuit board body (1) is provided with heat dissipation holes penetrating same from the base face (12) to the heat dissipation bonding pad (2); the base face (12) is provided with a bottom solder mask (3); the bottom solder mask (3) flows into the heat dissipation holes such that the heat dissipation holes are formed into semi-plug holes (13); reinforced solder masks (4) are arranged outside the bottom solder mask (3); and the reinforced solder masks cover the semi-plug holes in a sealing manner.

### CROSS-REFERENCE TO RELATED APPLICATION

The present application is a U.S. National Phase Entry of International Application No. PCT/CN2023/093986 having an international filing date of May 12, 2023, which claims priority to Chinese Patent Application No. 202210672765.4, filed to the China National Intellectual Property Administration on Jun. 14, 2022 and entitled “Circuit Board and Display Device Having Same”. Contents of the above-identified applications are incorporated herein by reference.

### TECHNICAL FIELD

Embodiments of the present disclosure relate to, but are not limited to, the field of electrical technology, and in particular to a circuit board and a display device having the same.

### BACKGROUND

On a circuit board, for a part with a heat dissipation bonding pad in a center thereof, it is necessary to punch semi-plug holes when designing the circuit board so as to dissipate heat from the heat dissipation bonding pad, thereby achieving better heat dissipation effect.

### SUMMARY

The following is a summary of subject matters described herein in detail. This summary is not intended to limit the protection scope of the claims.

In a first aspect, an embodiment of the present disclosure provides a circuit board, including a circuit board body. A part mounting face is formed on one side of the circuit board body, and a base face is formed on the other side of the circuit board body opposite to the part mounting face. The part mounting face is provided with a heat dissipation bonding pad. The circuit board body is provided with heat dissipation holes penetrating from the base face to the heat dissipation bonding pad. The base face is provided with a bottom solder mask, and the bottom solder mask flows into the heat dissipation holes such that the heat dissipation holes are formed into semi-plug holes. Reinforced solder masks are provided outside the bottom solder mask, and the reinforced solder masks cover the semi-plug holes in a sealing manner.

In an exemplary embodiment, a semi-plug hole conduction portion is provided at a semi-plug hole. The semi-plug hole conduction portion includes a conduction portion body located in the semi-plug hole and a bottom bonding pad located on the base face. The conduction portion body is configured to be electrically connected to the heat dissipation bonding pad, the bottom bonding pad is configured to be electrically connected to the conduction portion body, the bottom solder mask covers the bottom bonding pad, and the reinforced solder masks cover the bottom bonding pad from outside the bottom solder mask in a sealing manner.

In an exemplary embodiment, the semi-plug hole conduction portion further includes a top bonding pad located on the part mounting face. The conduction portion body is configured to be electrically connected to the top bonding pad, and the top bonding pad is configured to be electrically connected to the heat dissipation bonding pad.

In an exemplary embodiment, a reinforced solder mask is circular, the bottom bonding pad is circular, and a difference between a diameter of the reinforced solder mask and a diameter of the bottom bonding pad is greater than or equal to 3 mil.

In an exemplary embodiment, a reinforced solder mask is triangular, quadrilateral, or pentagonal, the bottom bonding pad is triangular, quadrilateral, or pentagonal, and a difference between a size of the reinforced solder mask and a size of the bottom bonding pad is greater than or equal to 3 mil.

In an exemplary embodiment, the top bonding pad is formed by folding an end of the conduction portion body close to the part mounting face outward. The bottom bonding pad is formed by folding an end of the conduction portion body close to the base face outward.

In an exemplary embodiment, the top bonding pad and the heat dissipation bonding pad are constructed as one piece.

In an exemplary embodiment, a thickness of a reinforced solder mask is 0.3 mil to 0.7 mil.

In an exemplary embodiment, a quantity of the semi-plug holes corresponding to a single heat dissipation bonding pad is multiple.

In an exemplary embodiment, a quantity of the reinforced solder masks is consistent with the quantity of the semi-plug holes, and positions of the reinforced solder masks are in one-to-one correspondence to positions of the semi-plug holes.

In an exemplary embodiment, the part mounting face is provided with a top solder mask that avoids the heat dissipation bonding pad.

In an exemplary embodiment, thicknesses of the top solder mask and the bottom solder mask are 0.3 mil to 0.7 mil.

In an exemplary embodiment, the top solder mask and the bottom solder mask are green oil layers, and the reinforced solder masks are white oil layers.

In a second aspect, an embodiment of the present disclosure provides a display device including the circuit board described above.

Additional aspects and advantages of the embodiments of the present disclosure will be set forth in part in the following description, and in part will be apparent from the description, or may be learned through practice of the embodiments of the present disclosure.

Other aspects of the present disclosure may be comprehended after the drawings and the detailed descriptions are read and understood.

### BRIEF DESCRIPTION OF DRAWINGS

FIG. 1 is a schematic cross-sectional view of a circuit board according to an embodiment of the present disclosure;

FIG. 2 is a top view of a circuit board according to an embodiment of the present disclosure;

FIG. 3 is a bottom view of a circuit board according to an embodiment of the present disclosure; and

FIG. 4 is an enlarged schematic view of a semi-plug hole, a bottom bonding pad, and a reinforced solder mask according to an embodiment of the present disclosure.

### DETAILED DESCRIPTION

Embodiments of the present disclosure are described in detail below, and examples of the embodiments are illustrated in the drawings, in which the same or similar reference signs always denote the same or similar elements or elements having the same or similar functions. Embodiments described below with reference to the drawings are illustrative, and are merely intended to explain the embodiments of the present disclosure, which cannot be interpreted as a limitation on the present disclosure.

In the description of the embodiments of the present disclosure, it should be understood that orientation or position relationships indicated by terms “longitudinal”, “transverse”, “length”, “width”, “thickness”, “upper”, “lower”, “front”, “back”, “left”, “right”, “vertical”, “horizontal”, “top”, “bottom”, “inside”, “outside” and the like are based on the orientation or position relationships shown in the drawings, and are only for the convenience of description of the embodiments of the present disclosure and simplification of the description, but are not intended to indicate or imply that the mentioned device or element must have a specific orientation, or is constructed and operated in a particular orientation, and therefore they should not be construed as limitations on the embodiments of the present disclosure. Further, in the description of the embodiments of the present disclosure, “multiple” means at least two, for example, two, three, etc. unless explicitly and specifically defined otherwise.

In the embodiments of the present disclosure, unless otherwise clearly specified and defined, terms “installed”, “connected”, “coupled”, “fixed” and other terms should be broadly understood. For example, it may be a fixed connection or a detachable connection, or an integrated connection; or it may be a mechanical connection, or an electrical connection, or a communication with each other; or it may be a direct connection, or an indirect connection through an intermediary, or an internal communication between two elements or interaction between two elements. For those of ordinary skill in the art, specific meanings of the abovementioned terms in the embodiments of the disclosure can be understood according to a specific condition.

As mentioned earlier, at present, when designing a circuit board, it is necessary to punch semi-plug holes to dissipate heat from the heat dissipation bonding pad. However, the inventor found that due to the different control ability of plug hole rate in different factories, there is a risk that solder will easily flow into the semi-plug holes and overflow from the other side of the circuit board when melting, resulting in poor tin eating in the heat dissipation bonding pad and uneven distribution of solder, thus reducing the mounting accuracy.

In order to better seal the semi-plug holes, the present disclosure provides a circuit board and a display device having the same. The circuit board and the display device according to embodiments of the present disclosure are described in detail below with reference to FIGS. 1 to 4.

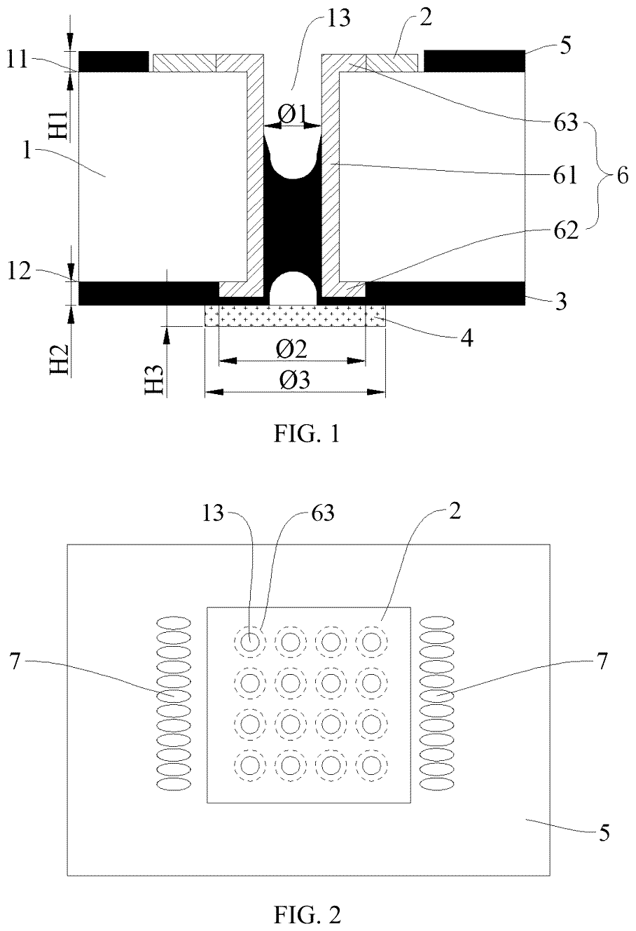

Referring to FIGS. 1 to 2, the circuit board (also called PCB board) according to an embodiment of the present disclosure may include a circuit board body 1. A part mounting face 11 is formed on one side of the circuit board body 1, and a base face 12 is formed on the other side of the circuit board 1 opposite to the part mounting face. For example, in FIG. 1, the part mounting face 11 is formed on a top side of the circuit board body 1, and the base face 12 is formed on a bottom side of the circuit board body. A part is adapted to be mounted on the part mounting face 11. Optionally, the part may be a chip, a resistor or the like.

The part mounting face 11 is provided with a heat dissipation bonding pad 2, and the heat dissipation bonding pad 2 corresponds to a center of the part. A plurality of common bonding pads 7 may be provided around the heat dissipation bonding pad 2, pins on both sides of the part may be welded and fixed with the common bonding pads 7, and the center of the part may be welded and fixed with the heat dissipation bonding pad 2.

The circuit board body 1 is provided with heat dissipation holes penetrating from the base face 12 to the heat dissipation bonding pad 2, so that a part of heat in the center of the part may be dissipated through the heat dissipation holes, and the other part of heat in the center of the part may be first transmitted to the heat dissipation bonding pad 2, and then dissipated from the heat dissipation holes through the heat dissipation bonding pad 2, thus effectively preventing the damage caused by excessive temperature of the part. As shown in FIG. 1, the heat dissipation holes penetrate the circuit board body 1 and the heat dissipation bonding pad 2 in an up and down direction.

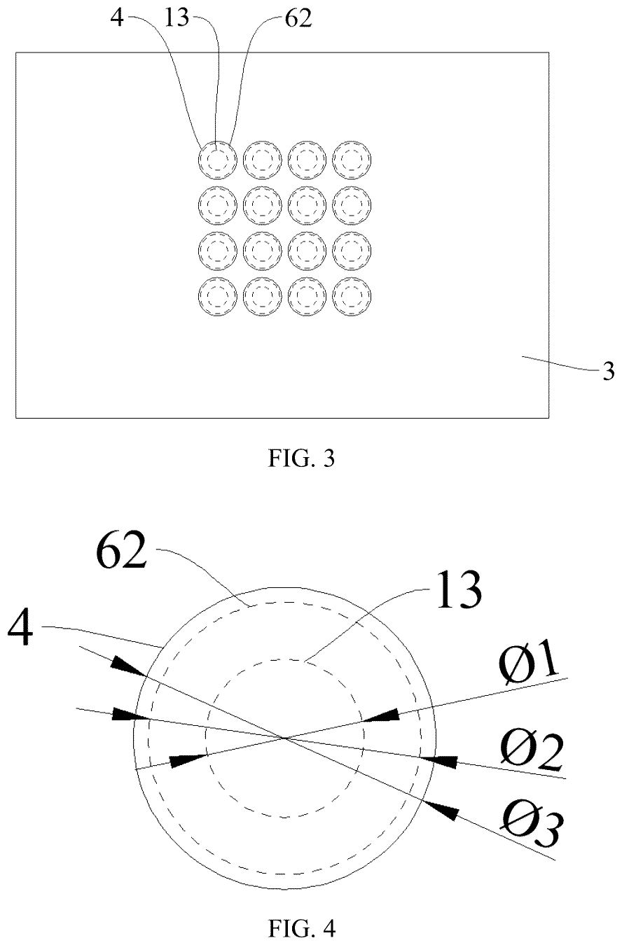

Referring to FIGS. 1 and 3, the base face 12 is provided with a bottom solder mask 3, which is a non-conductive material. The bottom solder mask 3 flows into the heat dissipation holes such that the heat dissipation holes are formed into semi-plug holes 13. The bottom solder mask 3 in the heat dissipation holes has a function of blocking the heat dissipation holes, so that solder paste will not flow from the heat dissipation holes to the base face 12 when soldering the part on the part mounting face 11. Reinforced solder masks 4 are provided outside the bottom solder mask 3, and the reinforced solder masks 4 cover the semi-plug holes 13 in a sealing manner. In other words, an edge of a reinforced solder mask 4 extends outward beyond an edge of a semi-plug hole 13, so that the reinforced solder mask 4 may well cover the semi-plug hole 13 from outside the bottom solder mask 3 in a sealing manner, thereby sealing the semi-plug hole 13 well without tin leakage.

According to the circuit board according to the embodiment of the present disclosure, by providing the reinforced solder masks 4, the semi-plug holes 13 of the circuit board are well sealed, and tin at the part may be prevented from leaking from the semi-plug holes 13 to the base face 12 from the part mounting face 11, which is beneficial to improving the mounting accuracy and the yield of the circuit board.

In an embodiment of the present disclosure, referring to FIGS. 1 to 4, a semi-plug hole conduction portion 6 is provided at the semi-plug hole 13. The semi-plug hole conduction portion 6 may include a conduction portion body 61 located in the semi-plug hole 13, and a bottom bonding pad 62 located on the base face 12. The conduction portion body 61 is configured to be electrically connected to the heat dissipation bonding pad 2, the bottom bonding pad 62 is configured to be electrically connected to the conduction portion body 61, and the bottom solder mask 3 covers the bottom bonding pad 62, so that a communication circuit may be formed between the part mounting face 11 and the base face 12.

The reinforced solder mask 4 covers the bottom bonding pad 62 from outside the bottom solder mask 3 in a sealing manner. In other words, the reinforced solder mask 4 is located on a side of the bottom solder mask 3 facing away from the circuit board body 1, and an edge of the reinforced solder mask 4 extends outward beyond an edge of the bottom bonding pad 62. Thus, the reinforced solder mask 4 may well cover the bottom bonding pad 62 from outside the bottom solder mask 3 in a sealing manner, and it is possible to cover the semi-plug hole 13 in a sealing manner. Therefore, it is not easy to leak tin at the semi-plug hole 13.

In the embodiment shown in FIGS. 1, 3 and 4, the semi-plug hole 13, the reinforced solder mask 4, and the bottom bonding pad 62 are all circular, and a diameter of the reinforced solder mask 4−a diameter of the bottom bonding pad 62≥3 mils. For example, in some embodiments, the diameter ø1 of the semi-plug hole 13 is 12 mil, the diameter ø2 of the bottom bonding pad 62 is 22 mil, the diameter ø3 of the reinforced solder mask 4 is 26 mil, and the diameter ø3 of the reinforced solder mask 4−the diameter ø2 of the bottom bonding pad 62 is=4 mil.

In some embodiments not shown in the figure, the reinforced solder mask 4 may have one or more of triangular, quadrilateral, pentagonal shape or the like, and the bottom bonding pad 62 may also have one or more of triangular, quadrilateral, pentagonal shape or the like, provided that the edge of the reinforced solder mask 4 extends outward beyond the edge of the bottom bonding pad 62.

In an embodiment of the present disclosure, referring to FIGS. 1 to 2, the semi-plug hole conduction portion 6 may further include a top bonding pad 63 located on the part mounting face 11. The conduction portion body 61 is configured to be electrically connected to the top bonding pad 63, and the top bonding pad 63 is configured to be electrically connected to the heat dissipation bonding pad 2. The top bonding pad 63 may be formed by folding a top end of the conduction portion body 61 outward, and the bottom bonding pad 62 may be formed by folding a bottom end of the conduction portion body 61 outward. The semi-plug hole conduction portion 6 is a conductor as a whole, for example, the semi-plug hole conduction portion 6 may be made of copper or aluminum.

In an embodiment, as shown in FIG. 1, the top bonding pad 63 and the heat dissipation bonding pad 2 may be constructed as one piece, i.e., the semi-plug hole conduction portion 6 and the heat dissipation bonding pad 2 may be constructed as one piece.

In an embodiment of the present disclosure, referring to FIG. 1, a thickness of the reinforced solder mask 4 is H3, where H3=0.3 mil to 0.7 mil. Alternatively, for example, the thickness H3 of the reinforced solder mask 4 may be 0.3 mil, 0.4 mil, 0.5 mil, 0.6 mil, or 0.7 mil. Alternatively, the thickness H3 of the reinforced solder mask 4 may further be other values between 0.3 mil and 0.7 mil, which will not be listed here.

In an embodiment of the present disclosure, referring to FIGS. 2 to 3, a quantity of the semi-plug holes 13 corresponding to a single heat dissipation bonding pad 2 is multiple, which is beneficial to increasing air volume at the heat dissipation bonding pad 2, thereby improving the heat dissipation efficiency of the heat dissipation bonding pad 2 and preventing the part at the heat dissipation bonding pad 2 from being damaged due to excessive temperature.

In an embodiment of the present disclosure, referring to FIGS. 1 and 3, a quantity of the reinforced solder masks 14 is consistent with the quantity of the semi-plug holes 13, and positions of the reinforced solder masks 14 are in one-to-one correspondence to positions of the semi-plug holes 13, so that the quantity of the reinforced solder masks 4 may be reduced and the weight of the circuit board may be reduced.

In an embodiment of the present disclosure, referring to FIGS. 1 to 2, a top solder mask 5 may be provided on the part mounting face 11. The top solder mask 5 is a non-conductive material, and the top solder mask 5 avoids the heat dissipation bonding pad 2. As shown in FIG. 1, the heat dissipation bonding pad 2 is exposed from the top solder mask 5, so that the electrical connection between the part and the heat dissipation bonding pad 2 will not be affected.

In an embodiment of the present disclosure, referring to FIG. 1, a thickness of the top solder mask 5 is H1, a thickness of the bottom solder mask 3 is H2, H1=0.3 mil to 0.7 mil, and H2=0.3 mil to 0.7 mil. For example, optionally, the thicknesses of the top solder mask 5 and the bottom solder mask 3 may be 0.3 mil, 0.4 mil, 0.5 mil, 0.6 mil, or 0.7 mil. Alternatively, the thicknesses of the top solder mask 5 and the bottom solder mask 3 may further be other values between 0.3 mil and 0.7 mil, which will not be listed here.

In an embodiment of the present disclosure, the top solder mask 5 and the bottom solder mask 3 may be solder mask ink layers, and the reinforced solder mask 4 may be a print ink layer. The reinforced solder mask 4 may be formed by printing an ink for printing characters at a position corresponding to the semi-plug hole 13 outside the bottom solder mask 3.

In an embodiment of the present disclosure, the top solder mask 5 and the bottom solder mask 3 are green oil layers, and the reinforced solder mask 4 is a white oil layer. White oil is often used for printing characters outside the green oil layer. By using white oil to form a reinforced solder mask 4, the original manufacturing equipment of the circuit board may be fully utilized, without adding additional equipment, that is, the printing of the reinforced solder mask 4 is completed during the process of printing characters, which is beneficial to saving the manufacturing cost of the circuit board. In addition, there is a great color difference between the white oil and the green oil. When the white oil is printed unevenly, it can be found in time, so that it is convenient to add a reinforced solder mask 4 to the position of the semi-plug hole 13, thereby improving the sealing effect of the semi-plug hole 13 and preventing tin leakage at the semi-plug hole 13. The reinforced solder mask 4 may also be called white screen printing.

In an embodiment, a process flow of the circuit board may be as follows: inner layer→pressing to form the circuit board body 1→drilling heat dissipation holes→electroplating→forming the heat dissipation bonding pad 2 and the semi-plug hole conduction portion 6→forming the bottom solder mask 3 and the top solder mask 5→using white oil to form the reinforced solder mask 4, and using white oil to print characters at a target position→treating surface→molding→electrically testing→inspecting finished product→packaging and shipping.

The sequence of equipment used in the process flow of the circuit board may be as follows: printing press→solder paste printing inspection machine→high-speed mounting machine→universal machine→reflow furnace→optical solder joint inspection machine→printing press→solder paste printing inspection machine→high-speed mounting machine→universal machine→reflow furnace→optical solder joint inspection machine.

A display device according to an embodiment in another aspect of the present disclosure includes the circuit board of the above-described embodiment.

According to the display device of the embodiment of the present disclosure, by adding the reinforced solder mask 4 at a corresponding position at a bottom of the semi-plug hole 13, the semi-plug hole 13 of the circuit board is well sealed without tin leakage, thereby preventing the problems of poor soldering and decreased mounting accuracy caused by tin leakage during soldering, and making the mounting of the circuit board more accurate and the yield higher.

In descriptions of this specification, descriptions with reference to terms “an embodiment,” “some embodiments,” “an example,” “a specific example,” or “some examples” or the like mean that a particular feature, a structure, a material, or a characteristic described in conjunction with the embodiment or the example is included in at least one embodiment or example of the present disclosure. In this specification, a schematic expression of the above terms does not necessarily refer to a same embodiment or example. Moreover, the specific features, structures, materials, or characteristics described may be combined in any one or more embodiments or examples in a proper way. Further, those skilled in the art may join and combine different embodiments or examples described in this specification.

Although the embodiments of the present disclosure have been shown and described above, it may be understood that the above embodiments are exemplary and cannot be interpreted as limitations on the embodiments of the present disclosure. An ordinary person skilled in the art may make changes, modifications, substitutions, and variations to the above embodiments within the scope of the present disclosure.

1. A circuit board, comprising: a circuit board body, wherein a part mounting face is formed on one side of the circuit board body; a base face is formed on the other side of the circuit board body opposite to the part mounting face; the part mounting face is provided with a heat dissipation bonding pad; the circuit board body is provided with heat dissipation holes penetrating from the base face to the heat dissipation bonding pad; the base face is provided with a bottom solder mask; the bottom solder mask flows into the heat dissipation holes such that the heat dissipation holes are formed into semi-plug holes; reinforced solder masks are provided outside the bottom solder mask; and the reinforced solder masks cover the semi-plug holes in a sealing manner.

2. The circuit board according to claim 1, wherein a semi-plug hole conduction portion is provided at a semi-plug hole; the semi-plug hole conduction portion comprises a conduction portion body located in the semi-plug hole and a bottom bonding pad located on the base face; the conduction portion body is configured to be electrically connected to the heat dissipation bonding pad; the bottom bonding pad is configured to be electrically connected to the conduction portion body; the bottom solder mask covers the bottom bonding pad; and the reinforced solder masks cover the bottom bonding pad from outside the bottom solder mask in a sealing manner.

3. The circuit board according to claim 2, wherein the semi-plug hole conduction portion further comprises a top bonding pad located on the part mounting face; the conduction portion body is configured to be electrically connected to the top bonding pad; and the top bonding pad is configured to be electrically connected to the heat dissipation bonding pad.

4. The circuit board according to claim 2, wherein a reinforced solder mask is circular; the bottom bonding pad is circular; and a difference between a diameter of the reinforced solder mask and a diameter of the bottom bonding pad is greater than or equal to 3 mil.

5. The circuit board according to claim 2, wherein a reinforced solder mask is triangular, quadrilateral, or pentagonal; the bottom bonding pad is triangular, quadrilateral, or pentagonal; and a difference between a size of the reinforced solder mask and a size of the bottom bonding pad is greater than or equal to 3 mil.

6. The circuit board according to claim 5, wherein the top bonding pad is formed by folding an end of the conduction portion body close to the part mounting face outward; and the bottom bonding pad is formed by folding an end of the conduction portion body close to the base face outward.

7. The circuit board according to claim 5, wherein the top bonding pad and the heat dissipation bonding pad are constructed as one piece.

8. The circuit board according to claim 1, wherein a thickness of a reinforced solder mask is 0.3 mil to 0.7 mil.

9. The circuit board according to claim 1, wherein a quantity of the semi-plug holes corresponding to a single heat dissipation bonding pad is multiple.

10. The circuit board according to claim 9, wherein a quantity of the reinforced solder masks is consistent with a quantity of the semi-plug holes, and positions of the reinforced solder masks are in one-to-one correspondence to positions of the semi-plug holes.

11. The circuit board according to claim 1, wherein the part mounting face is provided with a top solder mask that avoids the heat dissipation bonding pad.

12. The circuit board according to claim 11, wherein thicknesses of the top solder mask and the bottom solder mask are 0.3 mil to 0.7 mil.

13. The circuit board according to claim 11, wherein the top solder mask and the bottom solder mask are green oil layers, and the reinforced solder masks are white oil layers.

14. A display device, comprising the display circuit according to claim 1.

15. A display device, comprising the display circuit according to claim 2.

16. A display device, comprising the display circuit according to claim 3.

17. A display device, comprising the display circuit according to claim 4.

18. A display device, comprising the display circuit according to claim 5.

19. A display device, comprising the display circuit according to claim 6.

20. A display device, comprising the display circuit according to claim 7.
